(19) United States
(12) Patent Application Publication
(10) Pub. No.: US 2008/0212790 A1
(43) Pub. Date: Sep. 4, 2008

(54) SOUND EFFECT PROCESSING SYSTEM APPLIED TO COMPUTER

(76) Inventor: Hsin-Yuan Kuo, Kaohsiung County (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/019,591

(22) Filed: Jan. 24, 2008

(30) Foreign Application Priority Data
Feb. 13, 2007 (TW) 096202744

(51) Int. Cl. H03G 3/00

(52) U.S. Cl. 381/61

(57) ABSTRACT

A sound effect processing system applied to a computer includes a sound quality processing unit provided on the computer for processing and modifying sound quality as a signal frequency characteristic of sounds being input to or output from the computer, and a hardware sound quality adjustment control interface, via which a user may directly control the sound effect processing system to adjust sound signal frequencies and improve the sound quality without the need of using any software or driver.

### FIELD OF THE INVENTION

The present invention relates to a sound effect processing system applied to computer, and more particularly, to a sound effect processing system applied to computer that may be directly controlled by a user via a hardware sound quality adjustment control interface without the need of using any software or driver.

### BACKGROUND OF THE INVENTION

Computers are highly frequently used in people's daily life now to handle many different things. Meanwhile, more and more people use a computer to listen music. Generally, a computer is equipped with electronic devices for processing sound effect, such as a sound effect card. However, these electronic devices are designed for adjusting the sound quality through specific software and do not include any hardware for adjusting the quality of sound signals.

It is desirable to develop a sound effect processing system applied to computer, which allows a user to directly control it via a hardware interface to adjust sound signal frequencies and improve sound quality without the need of using any software or driver.

### SUMMARY OF THE INVENTION

A primary object of the present invention is to develop a sound effect processing system, so that a user may use a hardware sound quality adjustment control unit to control a sound quality processing unit on a computer to process and modify the sound quality as a signal frequency characteristic of sounds input to or output from the computer.

To achieve the above and other objects, the sound effect processing system applied to computer according to the present invention includes a sound quality processing unit provided on a computer for processing and modifying sound quality as a signal frequency characteristic of sounds being input to or output from the computer, and a hardware sound quality adjustment control interface, via which a user may directly control the sound effect processing system to adjust sound signal frequencies and improve the sound quality without the need of using any software or driver.

In the present invention, the hardware sound quality adjustment control interface adjusts and controls the sound quality processing unit.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a systematic view of a sound effect processing system applied to computer according to a first preferred embodiment of the present invention;

FIG. 2 is a systematic view of a sound effect processing system applied to computer according to a second preferred embodiment of the present invention;

FIG. 3 is a systematic view of a sound effect processing system applied to computer according to a third preferred embodiment of the present invention; and

FIG. 4 is a systematic view of a sound effect processing system applied to computer according to a fourth preferred embodiment of the present invention.

### DETAILED DESCRIPTION OF THE PREFERRED EMBODIMENTS

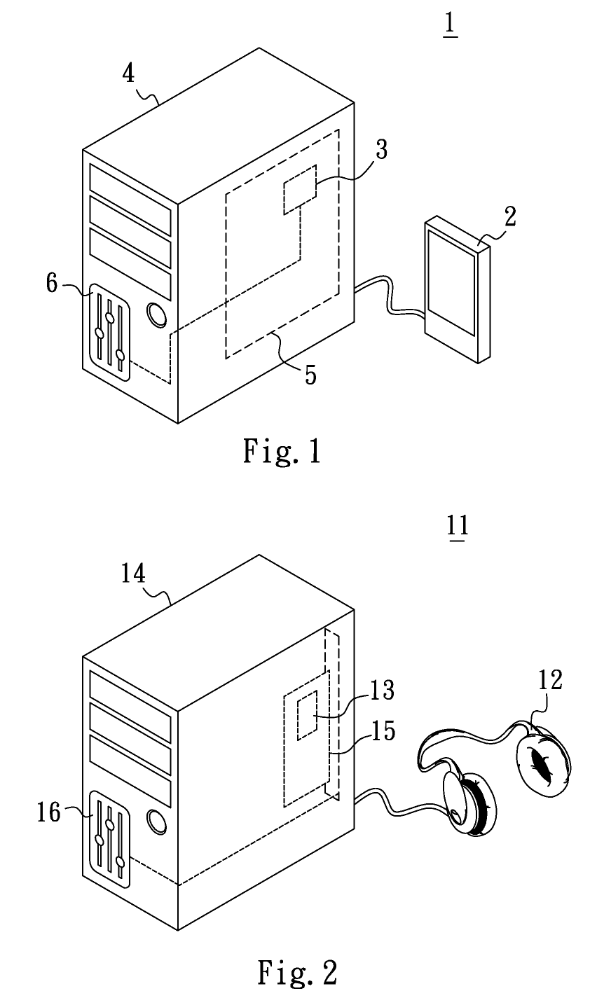

Please refer to FIG. 1 that is a systematic view of a sound effect processing system applied to computer according to a first preferred embodiment of the present invention. As shown, the sound effect processing system in the first embodiment, which is generally denoted a reference numeral 1, includes at least one output unit 2 for outputting sounds, such as a loudspeaker; a sound quality processing unit 3, such as an equalizer or a firmware stored on a read-only memory (ROM), being in the form of a chip or a circuit provided on a main board 5 of a computer 4 for processing and modifying the sound quality as a signal frequency characteristic of sounds before the sounds are output via the output unit 2; and a hardware sound quality adjustment control interface 6, such as at least one push key, a turning knob, or a slidable adjusting key, being provided on the computer 4 for adjusting and controlling the sound quality processing unit 3. The sound quality processing unit 3 processes and modifies not only the signal frequency characteristic of sounds output from the computer 4, but also the signal frequency characteristic of sounds input to the computer 4.

FIG. 2 is a systematic view of a sound effect processing system applied to computer according to a second preferred embodiment of the present invention. As shown, the sound effect processing system in the second embodiment, which is generally denoted a reference numeral 11, includes at least one output unit 12 for outputting sounds, such as a headphone; a sound quality processing unit 13, such as an equalizer or a firmware stored on a read-only memory (ROM), being in the form of a chip or a circuit provided on a sound effect card 15, which is internally connected to a computer 14, for processing and modifying the sound quality as a signal frequency characteristic of sounds before the sounds are output via the output unit 12; and a hardware sound quality adjustment control interface 16, such as at least one push key, a turning knob, or a slidable adjusting key, being provided on the computer 14 for adjusting and controlling the sound quality processing unit 13. The sound quality processing unit 13 processes and modifies not only the signal frequency characteristic of sounds output from the computer 14, but also the signal frequency characteristic of sounds input to the computer 14.

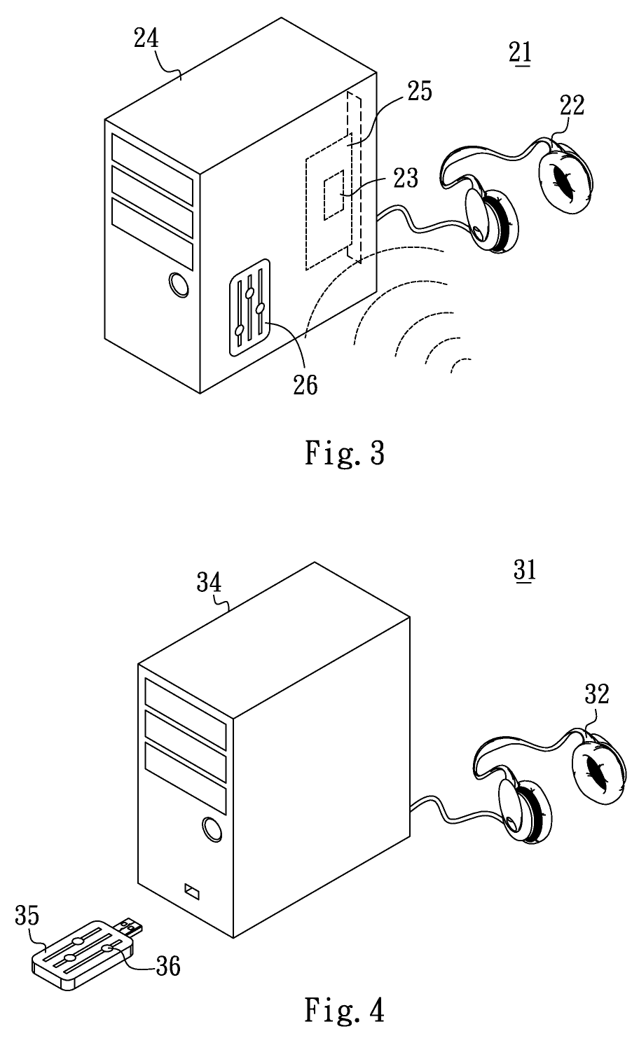

FIG. 3 is a systematic view of a sound effect processing system applied to computer according to a third preferred embodiment of the present invention. As shown, the sound effect processing system in the third embodiment, which is generally denoted a reference numeral 21, includes at least one output unit 22 for outputting sounds, such as a headphone; a sound quality processing unit 23, such as an equalizer or a firmware stored on a read-only memory (ROM), being in the form of a chip or a circuit provided on a sound effect card 25, which is internally connected to a computer 24, for processing and modifying the sound quality as a signal frequency characteristic of sounds before the sounds are output via the output unit 22; and a hardware sound quality adjustment control interface 26, such as a wireless remote controller, being provided on the computer 24 for adjusting and controlling the sound quality processing unit 23. The sound quality processing unit 23 processes and modifies not only the signal frequency characteristic of sounds output from the computer 24, but also the signal frequency characteristic of sounds input to the computer 24.

FIG. 4 is a systematic view of a sound effect processing system applied to computer according to a fourth preferred embodiment of the present invention. As shown, the sound effect processing system in the fourth embodiment, which is generally denoted a reference numeral 31, includes at least one output unit 32 for outputting sounds, such as a headphone; a sound quality processing unit (not shown) being in the form of a chip or a circuit provided on a sound effect card 35, which is externally connected to a computer 34, for processing and modifying the sound quality as a signal frequency characteristic of sounds before the sounds are output via the output unit 32; and a hardware sound quality adjustment control interface 36, such as at least one push key, a turning knob, or a slidable adjusting key, being provided on the sound effect card 35 for adjusting and controlling the sound quality processing unit. The sound quality processing unit processes and modifies not only the signal frequency characteristic of sounds output from the computer 34, but also the signal frequency characteristic of sounds input to the computer 34.

In brief, in the present invention, there is includeda sound qualityprocessing unit forprocessing and modifying the sound quality as a signal frequency characteristic of sounds, and a hardware sound quality adjustment control interface, via which a user may directly control the sound effect processing system to adjust the frequencies of sound signals and achieve the effect of improving sound quality without using any software or driver. Therefore, the sound effect processing system applied to computer according to the present invention and products derived from the present invention are industrially valuable for use to fully meet consumers' demands.

What is claimed is:

1. A sound effect processing system applied to a computer, comprising:
a sound quality processing unit for processing and modifying a signal frequency characteristic of sounds; and
a hardware sound quality adjustment control interface for adjusting and controlling the sound quality processing unit.

2. The sound effect processing system applied to computer as claimed in claim 1, further comprising at leas tone output unit for outputting the processed and modified sounds.

3. The sound effect processing system applied to computer as claimed in claim 2, wherein the output unit is selected from the group consisting of at least one headphone and at least one loudspeaker.

4. The sound effect processing system applied to computer as claimed in claim 1, wherein the sound quality processing unit is provided on a mainboard of the computer and selected from the group consisting of a chip and a circuit.

5. The sound effect processing system applied to computer as claimed in claim 1, wherein the sound quality processing unit is provided on a sound effect card and selected from the group consisting of a chip and a circuit.

6. The sound effect processing system applied to computer as claimed in claim 5, wherein the sound effect card is internally connected to the computer.

7. The sound effect processing system applied to computer as claimed in claim 5, wherein the sound effect card is externally connected to the computer.

8. The sound effect processing system applied to computer as claimed in claim 1, wherein the sound quality processing unit is an equalizer.

9. The sound effect processing system applied to computer as claimed in claim 1, wherein the sound quality processing unit is a firmware stored on an ROM.

10. The sound effect processing system applied to computer as claimed in claim 1, wherein the hardware sound quality adjustment control interface is provided on the computer.

11. The sound effect processing system applied to computer as claimed in claim 7, wherein the hardware sound quality adjustment control interface is provided on the sound effect card.

12. The sound effect processing system applied to computer as claimed in claim 1, wherein the hardware sound quality adjustment control interface includes at least one push key.

13. The sound effect processing system applied to computer as claimed in claim 1, wherein the hardware sound quality adjustment control interface includes a turning knob.

14. The sound effect processing system applied to computer as claimed in claim 1, wherein the hardware sound quality adjustment control interface includes a slidable adjusting key.

15. The sound effect processing system applied to computer as claimed in claim 1, wherein the hardware sound quality adjustment control interface includes a wireless remote controller.

16. The sound effect processing system applied to computer as claimed in claim 1, wherein the sound quality processing unit processes and modifies the signal frequency characteristic of sounds input to the computer.

17. The sound effect processing system applied to computer as claimed in claim 1, wherein the sound quality processing unit processes and modifies the signal frequency characteristic of sounds output from the computer.
